(19) United States
(12) Patent Application Publication
(10) Pub. No.: US 2026/0191020 A1
(43) Pub. Date: Jul. 2, 2026

(54) SEMICONDUCTOR PACKAGE

(71) Applicant: SAMSUNG ELECTRONICS CO., LTD., Suwon-si (KR)

(72) Inventors: SEUNGWAN SHIN, Suwon-si (KR); JINSU KIM, Suwon-si (KR)

(73) Assignee: SAMSUNG ELECTRONICS CO., LTD., Suwon-si (KR)

(21) Appl. No.: 19/265,233

(22) Filed: Jul. 10, 2025

(30) Foreign Application Priority Data
Dec. 26, 2024 (KR) 10-2024-0197474

(51) Int. Cl. H01L 23/544; H01L 23/31; H01L 23/498; H01L 23/522; H01L 23/538; H01L 25/065

(52) U.S. Cl. CPC H10W 46/00; H10W 70/611; H10W 70/635; H10W 70/65; H10W 74/137; H10W 90/701; H10W 20/40; H10W 46/301; H10W 90/00

(57) ABSTRACT

Provided is a semiconductor package including a substrate including a first aligning pattern that includes an opening, an under bump pattern parallel to the first aligning pattern, an insulation layer on at least a portion of each of the first aligning pattern and the under bump pattern, and a second aligning pattern including a first area on the first aligning pattern, at least a portion of the first area of the second aligning pattern overlapping the opening of the first aligning pattern and being embedded in the insulation layer, a bump structure on the under bump pattern, and at least one semiconductor chip on the substrate opposite to the bump structure, wherein the second aligning pattern includes a material that is different from a material included in the first aligning pattern.

### CROSS-REFERENCE TO RELATED APPLICATION

This application claims priority to Korean Patent Application No. 10-2024-0197474 filed with the Korean Intellectual Property Office on Dec. 26, 2024, the disclosure of which is incorporated herein in its entirety by reference.

### BACKGROUND

### 1. Field

Embodiments of the present disclosure relate to a semiconductor package.

### 2. Description of Related Art

Regarding a semiconductor package, bump structures may be formed on an under bump metal (UBM) of a substrate to electrically connect the semiconductor package to other components. As a related bump structure, a C4 bump formed with solder and having a shape ranging from a spherical shape to a hemispherical shape has been mainly used, but due to demands for reducing wire pitches and improving mechanical strength, the application of a pillar bump formed with a solder cap on a copper (Cu) pillar is being required.

### SUMMARY

One or more embodiments provide a semiconductor package including an aligning pattern for performing an align key function when penetration defects are generated.

An aspect of one or more embodiments, there is provided a semiconductor package including a substrate including a first aligning pattern that includes an opening, an under bump pattern parallel to the first aligning pattern, an insulation layer on at least a portion of each of the first aligning pattern and the under bump pattern, and a second aligning pattern including a first area on the first aligning pattern, at least a portion of the first area of the second aligning pattern overlapping the opening of the first aligning pattern and being embedded in the insulation layer, a bump structure on the under bump pattern, and at least one semiconductor chip on the substrate opposite to the bump structure, wherein the second aligning pattern includes a material that is different from a material included in the first aligning pattern.

According to another aspect of one or more embodiments, there is provided a semiconductor package including a substrate including a first redistribution structure, a bridge chip on a first surface of the first redistribution structure, a first encapsulant on at least a portion of the bridge chip, a second redistribution structure on the first encapsulant and electrically connected to the bridge chip, and a conductive post embedded in the first encapsulant and electrically connecting the first redistribution structure and the second redistribution structure, a bump structure on a second surface of the first redistribution structure, a first semiconductor chip on the second redistribution structure and electrically connected to the second redistribution structure, a second semiconductor chip on the second redistribution structure and electrically connected to the second redistribution structure, the second semiconductor chip being parallel to the first semiconductor chip, and a second encapsulant on at least a portion of each of the first semiconductor chip and the second semiconductor chip, wherein the first redistribution structure includes a first aligning pattern including an opening, an under bump pattern which parallel to the first aligning pattern, the bump structure being on the under bump pattern, an insulation layer on at least a portion of each of the first aligning pattern and the under bump pattern, and a second aligning pattern including a first area on the first aligning pattern, at least a portion of the first area of the second aligning pattern overlapping the opening of the first aligning pattern and being embedded in the insulation layer and a second area in the opening of the first aligning pattern, wherein the bridge chip electrically connects the first semiconductor chip and the second semiconductor chip, and wherein the second aligning pattern includes a material that is different from a material included in the first aligning pattern.

According to still another aspect of one or more embodiments, there is provided a semiconductor package including a substrate including a first aligning pattern including an opening, an under bump pattern parallel to the first aligning pattern, a first insulation layer on at least a portion of each of the first aligning pattern and the under bump pattern, a second aligning pattern including a first area on the first aligning pattern, at least a portion of the first area of the second aligning pattern overlapping the opening of the first aligning pattern and being embedded in the first insulation layer, and a second area in the opening of the first aligning pattern, a first wire pattern on the first insulation layer, a second insulation layer on at least a portion of each of the second aligning pattern and the first wire pattern, and a second wire pattern on the second insulation layer, a bump structure on the under bump pattern, a first semiconductor chip on the substrate opposite to the bump structure, and electrically connected to the substrate, a second semiconductor chip on the substrate and electrically connected to the substrate, the second semiconductor chip being parallel to the first semiconductor chip, and an encapsulant on at least a portion of each of the first semiconductor chip and the second semiconductor chip, wherein the substrate electrically connects the first semiconductor chip and the second semiconductor chip, and wherein the second aligning pattern includes a material that is different from a material included in the first aligning pattern.

According to still another aspect of one or more embodiments, there is provided a method for manufacturing a semiconductor package including manufacturing a substrate, arranging a semiconductor chip on a first surface of the substrate, and forming bump structures on a second surface opposite to the first surface of the substrate, wherein the manufacturing of a substrate includes forming a first aligning pattern having an opening on a conductive foil layer, forming an under bump pattern in parallel to the first aligning pattern, forming an insulation layer on at least a portion of each of the first aligning pattern and the under bump pattern, and forming a second aligning pattern including a first area on the first aligning pattern and embedded in the insulation layer so that at least a portion of the first area of the second aligning pattern overlaps the opening of the first aligning pattern.

### BRIEF DESCRIPTION OF DRAWINGS

Embodiments will be more clearly understood from the following detailed description taken in conjunction with the accompanying drawings in which:

FIG. 1 shows a cross-sectional view of a semiconductor package according to one or more embodiments;

FIG. 2 shows an enlarged view of a region A of FIG. 1;

FIGS. 3, 4, 5, 6, 7, and 8 show variations of a region A of FIG. 1;

FIG. 9 shows a cross-sectional view of a semiconductor package according to one or more other embodiments;

FIG. 10 shows a cross-sectional view of a semiconductor package according to one or more other embodiments;

FIGS. 11, 12, 13, 14, 15, 16, 17, 18, 19, 20, 21, 22, 23, 24, 25, 26, 27, 28, 29, 30, 31, 32, and 33 show a process for manufacturing a semiconductor package according to one or more embodiments.

FIGS. 34, 35, 36, and 37 show a process for manufacturing a semiconductor package according to a related embodiment.

### DETAILED DESCRIPTION

In the following detailed description, embodiments of the present disclosure have been shown and described, simply by way of illustration. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

Throughout this specification and the claims that follow, when it is described that an element is “coupled” to another element, the element may be “directly coupled” to the other element or “indirectly coupled” to the other element through a third element. In a similar sense, this includes being “physically connected” as well as being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

Throughout the specification, sequential numbers such as first and second are used to distinguish a constituent element from other constituent elements that are the same or similar to it, and are not necessarily intended to refer to a specific constituent element. Accordingly, a component referred to as the first constituent element in one part of this specification may be referred to as a second constituent element in another part of this specification.

References to any constituent element in the singular form include references to plurality of those constituent elements, unless specifically stated to the contrary. For example, an insulating layer may be used to mean not only one insulating layer, but also a plurality of insulating layers, such as two, three or more. Similarly, the component described as plural may be implemented as a single component.

The references to one side and the other side are intended to distinguish between different sides, and are not necessarily intended to limit it to a specific side. Accordingly, a side referred to as one side in a particular part of this specification may be referred to as the other side in other parts of this specification.

References to directions such as upper surface, upper side, upper part, lower surface, lower side, and lower part are intended to aid description and understanding with reference to the drawings.

Semiconductor packages according to embodiments of the present disclosure and a manufacturing method thereof will now be described with reference to accompanying drawings.

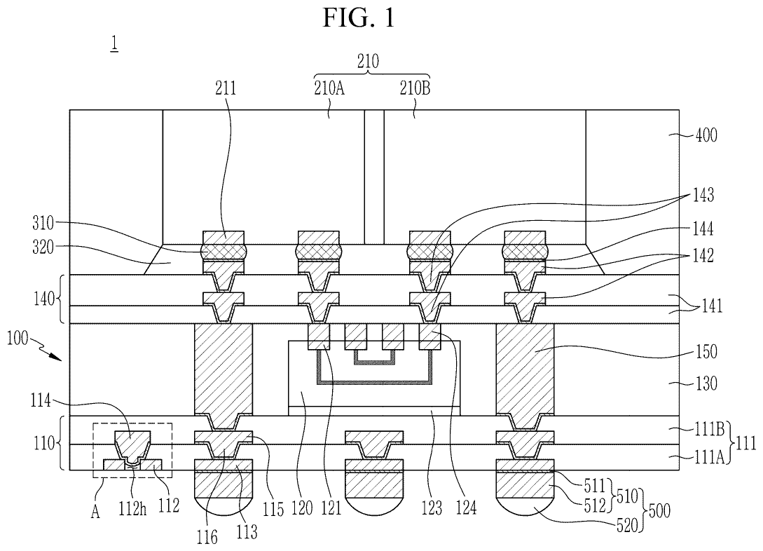

FIG. 1 shows a cross-sectional view of a semiconductor package according to one or more embodiments.

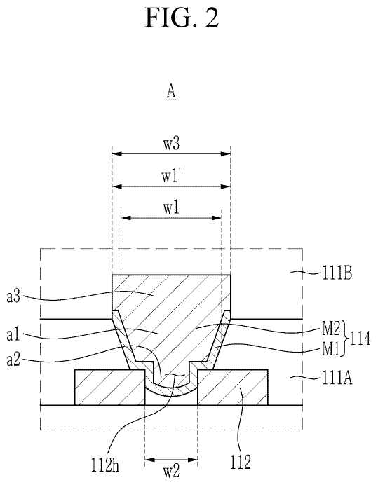

FIG. 2 shows an enlarged view of a region A of FIG. 1.

A substrate 100 of the semiconductor package 1 according to one or more embodiments may include under bump patterns 113, a first aligning pattern 112 arranged in parallel to the under bump patterns 113 and having an opening 112h, and a second aligning pattern 114 arranged on the first aligning pattern 112.

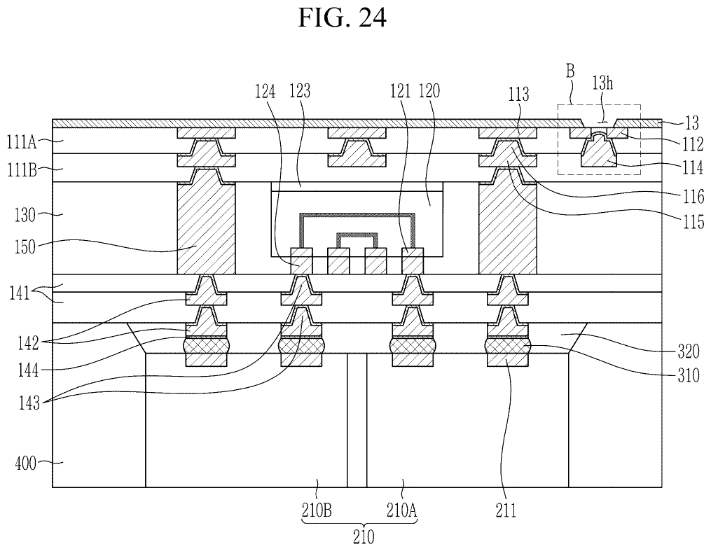

Bump structures 500 for electrically connecting the semiconductor package 1 and other elements may be formed on the under bump patterns 113 of the substrate 100. During a process for manufacturing the semiconductor package 1, a conductive foil layer 13 functioning as a seed layer for forming the bump structures 500 may be arranged on a lower surface of the substrate 100, and the first aligning pattern 112 performing an align key function for forming the bump structures 500 by removing at least a portion of the conductive foil layer 13 may be exposed (see FIG. 24). When the first aligning pattern 112 is processed together while removing the conductive foil layer 13, and penetration defects are generated, the first aligning pattern 112 may be damaged so that recognizing positions of the under bump patterns 113 through the first aligning pattern 112 may be difficult.

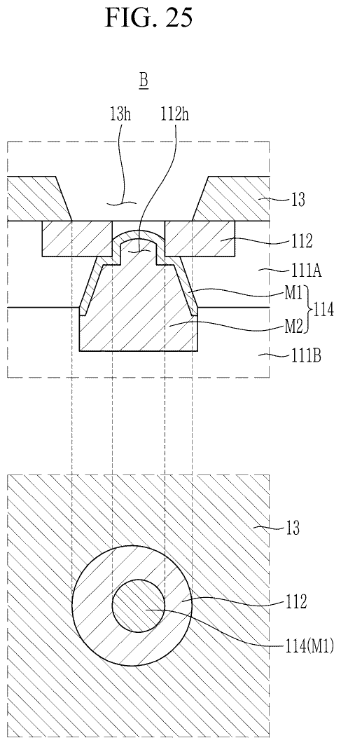

The semiconductor package 1 further includes a second aligning pattern 114 for performing an auxiliary align key function for forming bump structure 500 on the first aligning pattern 112 of the substrate 100. According to one or more embodiments, when the penetration defects are generated to the first aligning pattern 112, the positions of the under bump patterns 113 may be recognized through the second aligning pattern 114, and forming positions of the bump structures 500 may be set. Effects according to the present disclosure will be described in detail with reference to FIG. 25 to FIG. 27.

The semiconductor package 1 will now be described in detail.

The semiconductor package 1 may include a substrate 100 including a first redistribution structure 110, a bridge chip 120, a first encapsulant 130, a second redistribution structure 140, and conductive posts 150; at least one semiconductor chip 210 arranged on an upper surface of the substrate 100, a second encapsulant 400 adjacent to and surrounding at least a portion of the semiconductor chip 210, and bump structures 500 arranged on a lower surface of the substrate 100.

Regarding the semiconductor package 1, the first aligning pattern 112 and the second aligning pattern 114 may be included in the first redistribution structure 110. The first redistribution structure 110 may include, for example, the insulation layers 111, the first aligning pattern 112 with an opening 112h, the under bump patterns 113, the second aligning pattern 114, wire patterns 115, and vias 116.

The insulation layers 111 may include, for example, a first insulation layer 111A and a second insulation layer 111B arranged on the first insulation layer 111A.

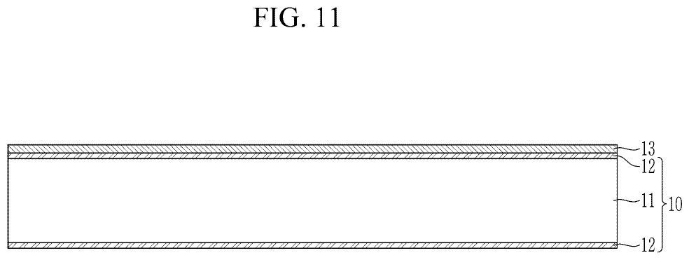

The first insulation layer 111A may be provided on and/or cover at least a portion of each of the first aligning pattern 112 and the under bump patterns 113. The first insulation layer 111A may be provided on and/or cover the first aligning pattern 112 and the under bump patterns 113 when forming the first aligning pattern 112 and the under bump patterns 113 on the conductive foil layer 13 (see FIG. 11 to 13). As the first aligning pattern 112, the under bump patterns 113, and the first insulation layer 111A are formed on the conductive foil layer 13, a lower surface of the first aligning pattern 112, lower surfaces of the under bump patterns 113, and a lower surface of the first insulation layer 111A may be coplanar.

The first insulation layer 111A may fill at least a portion of the opening 112h of the first aligning pattern 112, for example, a region that is not filled by a second area a2 of the second aligning pattern 114 from among the opening 112h of the first aligning pattern 112. As the first aligning pattern 112 in which the opening 112h is formed is covered with the first insulation layer 111A, the first insulation layer 111A may fill at least a portion of the opening 112h of the first aligning pattern 112. At least a portion of the region filling the opening 112h of the first aligning pattern 112 of the first insulation layer 111A may be removed in the process for forming the second aligning pattern 114, and may be filled with the second aligning pattern 114.

The second insulation layer 111B may be provided on and/or cover at least a portion of each of the second aligning pattern 114 and the wire patterns 115. A material and/or thickness of the second insulation layer 111B may be the same as a material and/or thickness of the first insulation layer 111A or may be different from the same.

The insulation layer 111 may be transparent or translucent. Hence, when a lower end of the second aligning pattern 114 is embedded in the insulation layer 111, the formation position of the bump structure 500 may be set by recognizing the position of the second aligning pattern 114 through a lower surface of the substrate 100.

The insulation layer 111 may include a photo-imageable dielectric (PID) to which a photolithography process is applicable. The insulation layer 111 may include other types of insulating materials such as thermosetting resin such as, for example, epoxy resin or thermoplastic resin such as polyimide (PI).

The first aligning pattern 112 may have an opening 112h for performing an align key function for forming a bump structure 500. The opening 112h may have a circular shape in a plan view, but is not limited thereto and may have various shapes. The position of the opening 112h of the first aligning pattern 112 may be recognized by a recognition device such as a mono camera, and the formation position of the bump structure 500 may be set based on the position of the recognized opening 112h. The position of the opening 112h of the first aligning pattern 112 may be recognized through the second aligning pattern 114 viewed from the lower surface of the substrate 100 through the opening 112h. A lower surface of the first aligning pattern 112 may not be covered and exposed by the first insulation layer 111A.

A conductive material may be used as a material of the first aligning pattern 112, and for example, metal such as copper (Cu), aluminum (Al), gold (Au), platinum (Pt), silver (Ag), tin (Sn), chromium (Cr), palladium (Pd), or titanium (Ti), or two or more alloys thereof may be used.

The under bump patterns 113 may be arranged in parallel with the first aligning pattern 112. Each of the under bump patterns 113 may be physically and electrically connected to the bump structure 500. A lower surface of the under bump pattern 113 may not be covered and exposed by the first insulation layer 111A.

A conductive material may be used as a material of the under bump patterns 113, and for example, metal such as copper (Cu), aluminum (Al), gold (Au), platinum (Pt), silver (Ag), tin (Sn), chromium (Cr), palladium (Pd), or titanium (Ti), or two or more alloys thereof may be used.

The first aligning pattern 112 and the under bump patterns 113 may be made by the same process, for example, a plating process, and may include the same material and/or may have the same thickness.

The second aligning pattern 114 may perform the auxiliary align key function for forming the bump structure 500. The second aligning pattern 114 may have a circular shape in a plan view, but is not limited thereto and may have various shapes.

In one or more embodiments, the second aligning pattern 114 may include a first area a1, a second area a2, and a third area a3. The first area a1, the second area a2, and the third area a3 of the second aligning pattern 114 describe respective areas of the second aligning pattern 114, and they may not have borders recognizable with each other by eyes of a user.

The second aligning pattern 114 may be made by forming a pattern groove penetrating a portion of the first insulation layer 111A in a thickness direction (vertical direction) perpendicular to the upper surface of the first insulation layer 111A or a pattern hole penetrating the entire first insulation layer 111A by removal of at least a portion of the first insulation layer 111A in the thickness direction from the upper surface of the first insulation layer 111A, and forming a conductive material to fill the pattern groove or the pattern hole and extend on the first insulation layer 111A. The pattern groove or the pattern hole may be formed by exposing and developing the first insulation layer 111A. The pattern groove or the pattern hole may be formed together with a via hole for forming the via 116. When forming the pattern groove or the pattern hole, the first aligning pattern 112 may not be processed, and may be exposed through the pattern groove or the pattern hole. The conductive material may be formed by forming a thin film portion M1 along a surface of the first insulation layer 111A and an exposed surface of the first aligning pattern 112 by a deposition process, and forming a filling portion M2 on the thin film portion M1 by a plating process. The second aligning pattern 114 may contact the first aligning pattern 112. For example, the first area a1 of the second aligning pattern 114 may contact an upper surface of the first aligning pattern 112, and the second area a2 may contact a wall of the opening 112h of the first aligning pattern 112.

The first area a1 of the second aligning pattern 114 may be arranged on an upper surface of the first aligning pattern 112 and may be embedded in the first insulation layer 111A so that at least a portion of the first area a1 of the second aligning pattern may overlap the opening 112h of the first aligning pattern 112 in the vertical direction. The first area a1 of the second aligning pattern 114 may be formed together with the via 116, may be arranged in parallel with the via 116, and may extend to a level on which an upper surface of the first insulation layer 111A is disposed in the vertical direction. A width w1 of the first area a1 of the second aligning pattern 114 in a horizontal direction parallel to the upper surface of the first insulation layer 111A may decrease in a downward direction toward the first aligning pattern 112 from the second aligning pattern 114. In the present disclosure, the width may represent the width in a cross-sectional view.

The second area a2 of the second aligning pattern 114 may extend from the first area a1 and may fill at least a portion of the opening 112h of the first aligning pattern 112. A width w2 of the second area a2 of the second aligning pattern 114 may be less than the width w1 of the first area a1 in the horizontal direction. In one or more embodiments, the second area a2 of the second aligning pattern 114 may include a region of which a center area protrudes downward compared to a peripheral area surrounding the center area and the width w2 is reduced in the downward direction. For example, a lower end of the second area a2 of the second aligning pattern 114 may include a curved surface. The lower end of the second area a2 of the second aligning pattern 114 may be covered with the first insulation layer 111A filling another portion of the opening 112h of the first aligning pattern 112.

The third area a3 of the second aligning pattern 114 may be arranged on the first area a1, may protrude on the first insulation layer 111A, and may be covered with the second insulation layer 111B. The third area a3 of the second aligning pattern 114 may be formed together with the wire pattern 115 and may be arranged in parallel with the wire pattern 115. A width w3 of the third area a3 of the second aligning pattern 114 may be equal to or less than a width w1′ of the first area a1 in the horizontal direction at an interface of the first area a1 and the third area a3. The width w1′ of the first area a1 may be a maximum width of the first area a1 at the interface of the first area a1 and the third area a3. A sufficient wire formation space on the first insulation layer 111A may be obtained by narrowing the width w3 of the third area a3 of the second aligning pattern 114. The second aligning pattern 114 may not include the third area a3 depending on the method for forming the second aligning pattern 114.

The second aligning pattern 114 may include a thin film portion M1 arranged along surfaces of the first insulation layer 111A and the first aligning pattern 112 and a filling portion M2 arranged on the thin film portion M1. The thin film portion M1 of the second aligning pattern 114 may be arranged between the first insulation layer 111A and the filling portion M2 and between the first aligning pattern 112 and the filling portion M2. The thin film portion M1 and/or the filling portion M2 may be configured with two or more layers. The thin film portion M1 may be formed by physical vapor deposition (PVD), chemical vapor deposition (CVD), and atomic layer deposition (ALD). The filling portion M2 may be formed by an electrolytic plating.

A conductive material may be used as a material of the second aligning pattern 114, and for example, metal such as copper (Cu), aluminum (Al), gold (Au), platinum (Pt), silver (Ag), tin (Sn), chromium (Cr), palladium (Pd), or titanium (Ti), or two or more alloys thereof may be used.

The second aligning pattern 114 may include a material that is different from the material of the first aligning pattern 112. At least the thin film portion M1 of the second aligning pattern 114 may include a material that is different from the material of the first aligning pattern 112. The second aligning pattern 114 may be recognized as an element distinguished from the first aligning pattern 112 by a recognition device such as a mono camera. In one or more embodiments, the position of the opening 112h of the first aligning pattern 112 may be recognized on the lower surface of the substrate 100 through the thin film portion M1 of the second aligning pattern 114 seen through the opening 112h so the first aligning pattern 112 may function as an align key. For example, the first aligning pattern 112 may include copper (Cu), the thin film portion M1 of the second aligning pattern 114 may include titanium (Ti), and the filling portion M2 may include copper (Cu). The thin film portion M1 of the second aligning pattern 114 may, for example, include a titanium (Ti) layer and a copper (Cu) layer arranged on the titanium (Ti) layer and disposed between the titanium (Ti) layer and the filling portion M2. When the thin film portion M1 of the second aligning pattern 114 includes titanium (Ti), adhesion strength between the first insulation layer 111A and the second aligning pattern 114 may increase, and it may be distinguished from the first aligning pattern 112 including copper (Cu) through the mono camera.

The wire patterns 115 may be arranged on the second insulation layer 111B. The wire patterns 115 arranged on the second insulation layer 111B may configure a wiring layer.

The vias 116 may be embedded in the insulation layer 111, and the respective vias 116 may connect the under bump pattern 113 and the wire pattern 115. The width of the via 116 may decrease in the downward direction to the under bump pattern 113 from the wire pattern 115.

Conductive materials may be used as materials of the wire pattern 115 and the via 116, and for example, metal such as copper (Cu), aluminum (Al), gold (Au), platinum (Pt), silver (Ag), tin (Sn), chromium (Cr), palladium (Pd), or titanium (Ti), or two or more alloys thereof may be used.

The wire pattern 115 and the via 116 may be integrally formed by forming a via hole in the first insulation layer 111A, forming a thin film portion along a wall and a bottom (a surface of the under bump pattern 113) of the via hole and the upper surface of the first insulation layer 111A by a deposition process, and forming a filling portion on the thin film portion by a plating process. The wire pattern 115 and the via 116 may be additionally formed.

According to the implementations, the insulation layer(s) 111 may be additionally arranged on the second insulation layer 111B. The wire patterns 115 may be arranged on the additionally arranged insulation layer 111 to configure a wiring layer, and the wire patterns 115 arranged on different layers may be connected through vias.

The bridge chip 120 may be arranged on an upper surface of the first redistribution structure 110. The bridge chip 120 may electrically connect the semiconductor chips 210, for example, a first semiconductor chip 120a and a second semiconductor chip 120b. The bridge chip 120 may be formed by forming the wiring layers and the insulation layers on a base substrate. The base substrate of the bridge chip 120 may include a semiconductor substrate such as a silicon substrate. As another example, the base substrate of the bridge chip 120 may include other types of insulation substrates such as an organic substrate or a glass substrate. The wiring layers of the bridge chip 120 may include a conductive material such as aluminum (Al) or copper (Cu), and the insulation layers of the bridge chip 120 may include an insulating material such as silicon oxide or silicon nitride.

The bridge chip 120 may include connection pads 121 for electrical connection with the second redistribution structure 140. The connection pads 121 may be electrically connected to the wiring layers of the bridge chip 120. The bridge chip 120 may be arranged so that the surface on which the connection pads 121 are arranged may face the second redistribution structure 140. The material of the connection pad 121 may use metal such as copper (Cu), aluminum (Al), gold (Au), platinum (Pt), silver (Ag), tin (Sn), chromium (Cr), palladium (Pd), or titanium (Ti), or two or more alloys thereof.

The bridge chip 120 may be attached to the first redistribution structure 110 through an adhesive member 123. The adhesive member 123 may be attached to the base substrate of the bridge chip 120, and be disposed between the first redistribution structure and the base substrate of the bridge chip 120. An adhesive material such as a die attach film (DAF) may be used as a material of the adhesive member 123.

The bridge chip 120 may be connected to the second redistribution structure 140 through a conductive pillar 124. The conductive pillar 124 may be arranged between the bridge chip 120 and the second redistribution structure 140 and may electrically connect the connection pad 121 of the bridge chip 120 and the second redistribution structure 140. At least a portion of the conductive pillar 124 may be embedded in the first encapsulant 130.

The material of the conductive pillar 124 may use metal such as copper (Cu), aluminum (Al), gold (Au), platinum (Pt), silver (Ag), tin (Sn), chromium (Cr), palladium (Pd), or titanium (Ti), or two or more alloys thereof.

The first encapsulant 130 may be provided on and/or cover at least a portion of the bridge chip 120. The first encapsulant 130 may be provided on and/or cover at least a portion of each of the conductive pillar 124 and the conductive post 150. The conductive post 150 and the conductive pillar 124 may be exposed through an upper surface of the first encapsulant 130. The upper surfaces of the conductive post 150, the conductive pillar 124, and the first encapsulant 130 may be coplanar. The first encapsulant 130 may be made of an epoxy molding compound (EMC) and thermosetting resin such as epoxy resin. The first encapsulant 130 may be formed by compression molding or transfer molding.

The second redistribution structure 140 may be arranged on the first encapsulant 130 and may be electrically connected to the bridge chip 120. The second redistribution structure 140 may be electrically connected to the first redistribution structure 110 through the conductive post 150.

The second redistribution structure 140 may include insulation layers 141, wire patterns 142, and vias 143.

The insulation layers 141 may be stacked. Each the insulation layer 141 may be provided on and/or cover at least a portion of the wire patterns 142 arranged on another insulation layer 141. The insulation layer arranged on the lowest side of the insulation layers 141 may be arranged on the first encapsulant 130 and may be provided on and/or cover upper surfaces of the conductive pillar 124 and the conductive post 150.

The insulation layer 141 may include a photo-imageable dielectric (PID). The insulation layer 141 may include may include different types of insulating materials including thermosetting resin such as, for example, epoxy resin and thermoplastic resin such as polyimide.

The wire patterns 142 may be arranged on the insulation layer 141. The wire patterns 142 arranged on the same insulation layer 141 may configure a wiring layer. An additional conductive layer 144 may be arranged on the wire patterns 142 (also referred to as wire pads) arranged on the uppermost insulation layer 141 from among the wire patterns 142. The additional conductive layer 144 may improve electric characteristic, solder wetness, and prevention of oxidation, for example, the additional conductive layer 144 may include gold (Au). A nickel (Ni) layer may be additionally arranged between the additional conductive layer 144 and the wire pattern 142 to reinforce bonding forces therebetween.

The vias 143 may be embedded in the insulation layer 141 and each of the vias 143 may connect the wire pattern 142 to the conductive pillar 124, the conductive post 150 or the wire pattern 142 arranged on another layer. The width of the via 143 may decrease in the downward direction.

The wire pattern 142 and the via 143 may use conductive materials as their materials, and for example, they may use metal such as copper (Cu), aluminum (Al), gold (Au), platinum (Pt), silver (Ag), tin (Sn), chromium (Cr), palladium (Pd), or titanium (Ti), or two or more alloys thereof.

The wire pattern 142 and the via 143 may be integrally formed by forming a via hole in the insulation layer 141, forming a thin film portion along the wall and the bottom of the via hole and an upper surface of the insulation layer 141 by a deposition process, and forming a filling portion on the thin film portion by a plating process. The wire pattern 142 and the via 143 may be individually formed.

The number of each of the insulation layers 141, the wire patterns 142, and the vias 143 of the second redistribution structure 140 is not limited to what is shown in the drawing, and the number may be greater or less than the same.

The conductive posts 150 may be embedded in the first encapsulant 130 and may electrically connect the first redistribution structure 110 and the second redistribution structure 140. A lower end of the conductive post 150 may be embedded in the second insulation layer 111B of the first redistribution structure 110 and may be connected to the wire pattern 115. As another example, a connection pad for connecting the conductive post 150 and the wire pattern 115 may be additionally formed on the second insulation layer 111B, and the conductive post 150 may be arranged on the connection pad.

A conductive material may be used as a material of the conductive post 150, and for example, metal such as copper (Cu), aluminum (Al), gold (Au), platinum (Pt), silver (Ag), tin (Sn), chromium (Cr), palladium (Pd), or titanium (Ti), or two or more alloys thereof may be used.

The conductive post 150 may be, similar to the wire patterns 115, formed by forming a thin film portion by a deposition process, and forming a filling portion on the thin film portion by a plating process.

The semiconductor chips 210 may be arranged in parallel on an upper surface of the substrate 100 and may be electrically connected to the substrate 100. The semiconductor chips 210 may be electrically connected to the second redistribution structure 140 and the bridge chip 120, and may be electrically connected to each other through the bridge chip 120. The semiconductor chips 210 may be electrically connected to the first redistribution structure 110 through the second redistribution structure 140 and the conductive post 150.

In one or more embodiments, the semiconductor chips 210 may include the first semiconductor chip 210A and the second semiconductor chip 210B arranged in parallel to each other on the second redistribution structure 140. The first semiconductor chip 210A may include a logic chip, and the second semiconductor chip 210B may include a memory chip. The logic chip may include at least one of an application processor (AP), a microprocessor, a central processing unit (CPU), a graphic processing unit (GPU), a neural processing unit (NPU), an application specific integrated circuit (ASIC), and a system on chip (SoC). The memory chip may include at least one of a high bandwidth memory (HBM) chip, a dynamic random access memory (DRAM) chip, a static random access memory (SRAM) chip, a flash memory chip, a read-only memory (ROM) chip, and a magnetic random access memory (MRAM) chip.

The semiconductor chip 210 may include connection pads 211 for electrical connection with the second redistribution structure 140. The semiconductor chip 210 may be arranged so that the surface on which the connection pads 211 are arranged may face the second redistribution structure 140. The material of the connection pad 211 may use metal such as copper (Cu), aluminum (Al), gold (Au), platinum (Pt), silver (Ag), tin (Sn), chromium (Cr), palladium (Pd), or titanium (Ti), or two or more alloys thereof.

The semiconductor chip 210 may be connected to the substrate 100 through the conductive bump 310. The conductive bump 310 may be arranged between the semiconductor chip 210 and the second redistribution structure 140 of the substrate 100 and may electrically connect the connection pad 211 of the semiconductor chip 210 and the second redistribution structure 140. The conductive bump 310 may be made of a conductive material such as solder.

The conductive bump 310 may be covered with an underfill member 320. The underfill member 320 may fill at least a portion of a space between the semiconductor chip 210 and the second redistribution structure 140, and may reduce a stress caused by a difference of the coefficients of thermal expansion (CTE) between the semiconductor chip 210 and the substrate 100. The underfill member 320 may be made of an insulating material such as epoxy resin, and if needed, may include a filler dispersed therein.

The second encapsulant 400 may cover or surround at least a portion of each of the semiconductor chips 210. Upper surfaces of the semiconductor chips 210 may be exposed through an upper surface of the second encapsulant 400. For example, the upper surfaces of the semiconductor chips 210 may be coplanar with the upper surface of the second encapsulant 00. The upper surfaces of the semiconductor chips 210 are not covered with and exposed by the second encapsulant 400, thereby increasing a heat radiation characteristic of the semiconductor package 1. The second encapsulant 400 may be made of, for example, an epoxy molding compound (EMC) and thermosetting resin such as epoxy resin. The second encapsulant 400 may be formed by a compression molding or a transfer molding.

The bump structure 500 may be arranged on the under bump pattern 113 disposed on a lower surface of the first redistribution structure 110.

The bump structure 500 may include a conductive pillar 510 and a conductive bump 520 arranged on the conductive pillar 510. The bump structure 500 including a conductive pillar 510 and a conductive bump 520 may be referred to as a pillar bump.

The conductive pillar 510 may include a thin film portion 511 and a filling portion 512. The conductive pillar 510 may be formed by using the conductive foil layer 13 arranged on the substrate 100 as the thin film portion 511, and forming the filling portion 512 on the thin film portion 511 by a plating process. The respective materials of the thin film portion 511 and the filling portion 512 may use a conductive material, and for example, may use metal such as copper (Cu), aluminum (Al), gold (Au), platinum (Pt), silver (Ag), tin (Sn), chromium (Cr), palladium (Pd), or titanium (Ti), or two or more alloys thereof.

The conductive bump 520 made of solder including an alloy (SnAg) of tin and silver. A lower end of the conductive bump 520 may have a substantially circular shape (e.g., spherical shape to hemispherical shape). The conductive bump 520 may be referred to as a solder cap.

A bonding reinforcing layer, for example, a nickel (Ni) layer, for reinforcing a bonding between the conductive pillar 510 and the conductive bump 520 may be additionally arranged between the same.

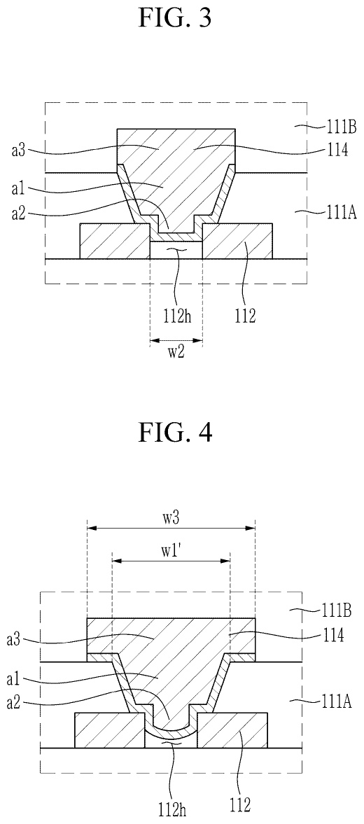

FIG. 3 to FIG. 8 show variations of a region A of FIG. 1.

Referring to FIG. 3, the width w2 of the second area a2 of the second aligning pattern 114 in the horizontal direction may be constant in the downward direction to the first aligning pattern 112 from the second aligning pattern 114. The lower end of the second area a2 of the second aligning pattern 114 may be substantially flat.

Referring to FIG. 4, the width w3 of the third area a3 of the second aligning pattern 114 may be greater than the width w1′ of the first area a1 in the horizontal direction at the interface of the first area a1 and the third area a3.

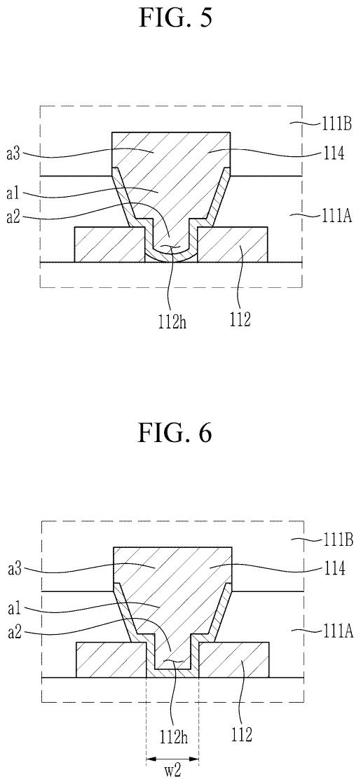

Referring to FIG. 5, the second area a2 of the second aligning pattern 114 may extend to a lower surface of the first insulation layer 111A from the first area a1 and may be exposed through the first insulation layer 111A. In the case of forming the second aligning pattern 114, when the first insulation layer 111A is entirely processed in the thickness direction to form a pattern hole, the second aligning pattern 114 may be exposed through the lower surface of the first insulation layer 111A.

Referring to FIG. 6, the width w2 of the second area a2 of the second aligning pattern 114 in the horizontal direction may be constant in the downward direction to the first aligning pattern 112 from the second aligning pattern 114. The lower end of the second area a2 of the second aligning pattern 114 may be substantially flat. The second area a2 of the second aligning pattern 114 may extend to a lower surface of the first insulation layer 111A from the first area a1 and may be exposed through the first insulation layer 111A.

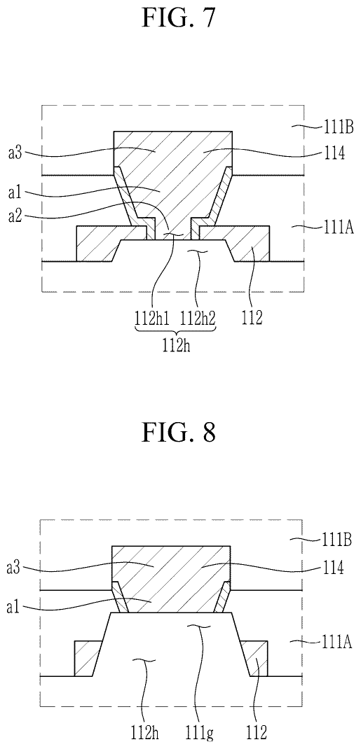

Referring to FIG. 7, in the case of removing the conductive foil layer 13, when the first insulation layer 111A, the first aligning pattern 112, and the second aligning pattern 114 are processed, a portion of each of them may be removed in the upward direction. A processing depth may be equal to or less than a thickness of the first aligning pattern 112 in the vertical direction, and a portion of the second area a2 of the second aligning pattern 114 may be removed together. After the processing, the opening 112h of the first aligning pattern 112 may include a first opening region 112h1 with a first width and a second opening region 112h2 with a second width that is greater than the first width in the horizontal direction. The second opening region 112h2 may represent the region expanded by a processing. The second area a2 of the second aligning pattern 114 may fill at least a portion of the first opening region 112h1 of the first aligning pattern 112, and may be exposed through the second opening region 112h2. The second opening region 112h2 of the first aligning pattern 112 may not be filled with the second aligning pattern 114.

Referring to FIG. 8, in the case of removing the conductive foil layer 13, when the first insulation layer 111A, the first aligning pattern 112, and the second aligning pattern 114 are processed together, a portion of each of them may be removed in the upward direction. The processing depth may be equal to or greater than the thickness of the first aligning pattern 112 in the vertical direction, and the entire second area a2 of the second aligning pattern 114 and a portion of the first area a1 may be removed. The second aligning pattern 114 may not include the second area a2. After a processing, the opening 112h of the first aligning pattern 112 may be defined to be a region expanded by the processing region. The first insulation layer 111A may have a groove portion 111g extending from the opening 112h of the first aligning pattern 112 in an upward direction, and the first area a1 of the second aligning pattern 114 may be exposed through the groove portion 111g of the first insulation layer 111A. The second aligning pattern 114 may not contact the first aligning pattern 112.

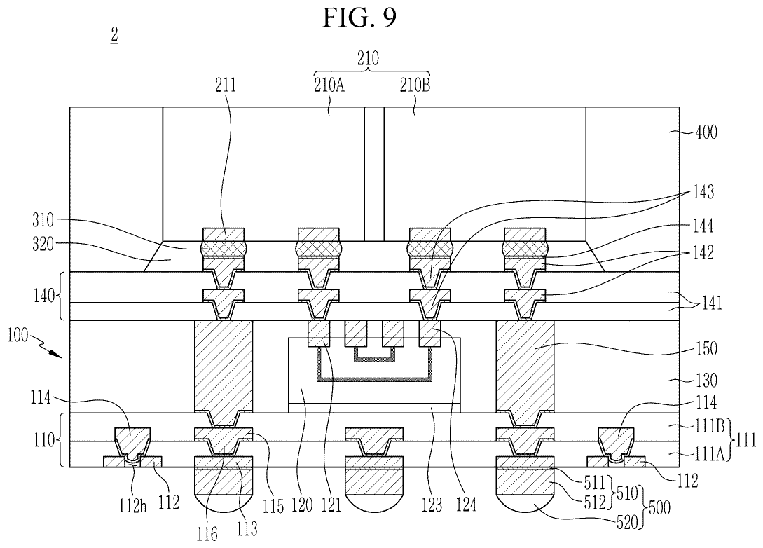

FIG. 9 shows a cross-sectional view on a semiconductor package according to one or more other embodiments.

The semiconductor package 2 may include first aligning patterns 112 and second aligning patterns 114. The first aligning patterns 112 and the second aligning patterns 114 may, for example, be arranged on respective sides of the under bump patterns 113. Accuracy of alignment may be increased by configuring multiple first aligning patterns 112 and second aligning patterns 114.

The same content as specifically described in the description of the semiconductor package 1 according to one or more embodiments of the present disclosure may be equally applied to the other elements.

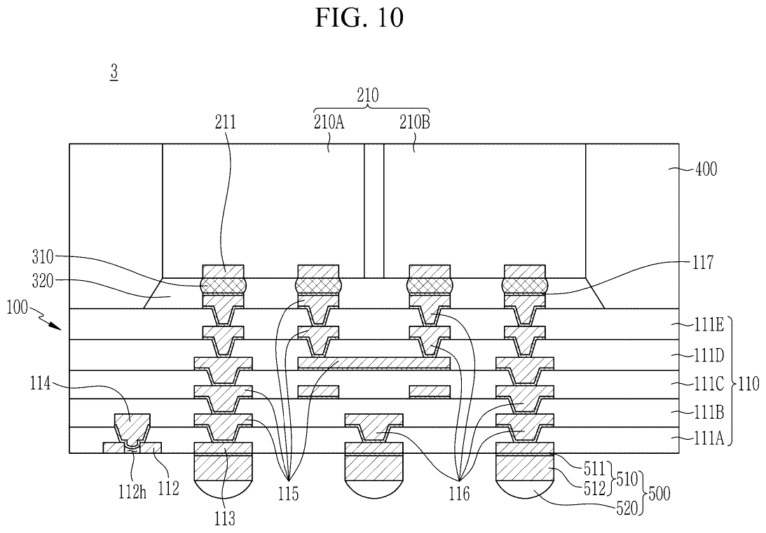

FIG. 10 shows a cross-sectional view on a semiconductor package according to one or more other embodiments.

The substrate 100 of the semiconductor package 3 has a different structure from the substrate 100 of the semiconductor package 1.

The substrate 100 does not include the bridge chip 120, and the semiconductor chips 210 may be electrically connected through the wire patterns 115 of the substrate 100. For example, the substrate 100 may be an organic interposer substrate.

The substrate 100 may include insulation layers 111, a first aligning pattern 112 with an opening 112h, under bump patterns 113, a second aligning pattern 114, wire patterns 115, and vias 116.

The insulation layers 111 may include, for example, a first insulation layer 111A, a second insulation layer 111B, a third insulation layer 111C, a fourth insulation layer 111D, and a fifth insulation layer 111E that are sequentially stacked in the vertical direction. However, the number of insulation layers 111 is not limited to that shown in the drawing and may be more or less than this.

The respective wire patterns 115 may be arranged on the insulation layer 111. The wire patterns 115 arranged on the same insulation layer 111 may configure a wiring layer, and the wire patterns 115 arranged on the insulation layer 111 may be connected to each other through the via 116. The width of the via 116 in the horizontal direction may decrease in the downward direction to the under bump pattern 113 from the wire pattern 115.

At least one additional conductive layer 117 may be arranged on the wire pattern 115 arranged on the fifth insulation layer 111E arranged on an uppermost portion from among the wire patterns 115. The additional conductive layer 117 may improve electric characteristic, solder wetness, and prevention of oxidation, for example, and may include gold (Au). A nickel (Ni) layer may be additionally arranged between the additional conductive layer 117 and the wire pattern 115 to reinforce the bonding forces therebetween.

The same content as specifically described in the description of the semiconductor package 1 according to one or more embodiments of the present disclosure may be equally applied to the other elements.

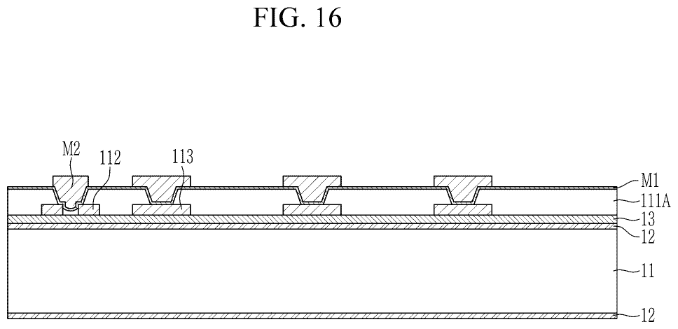

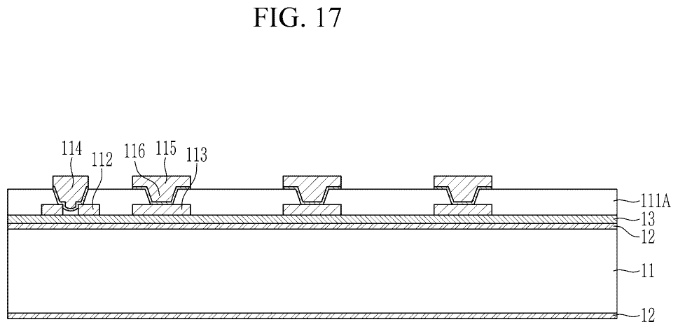

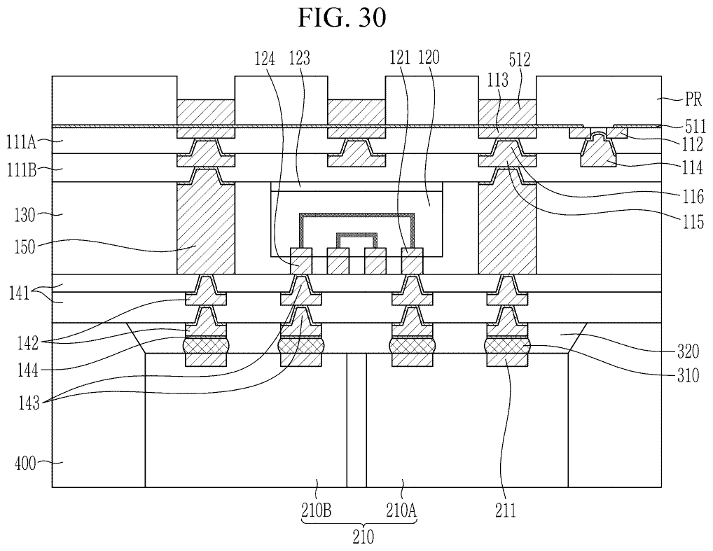

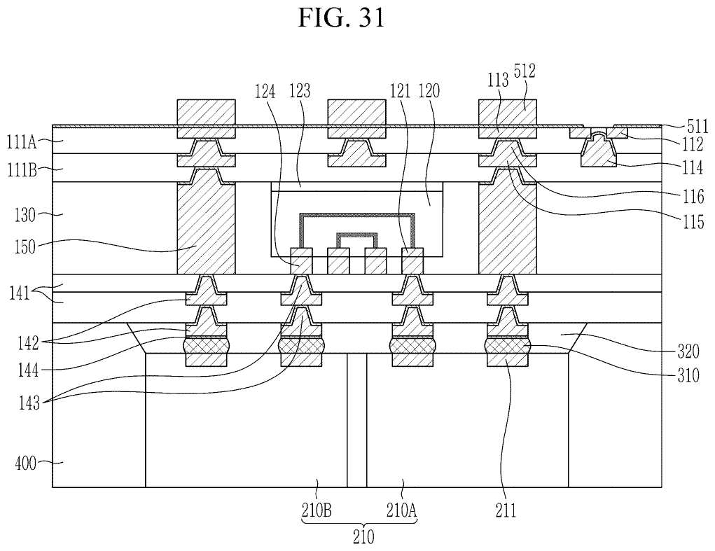

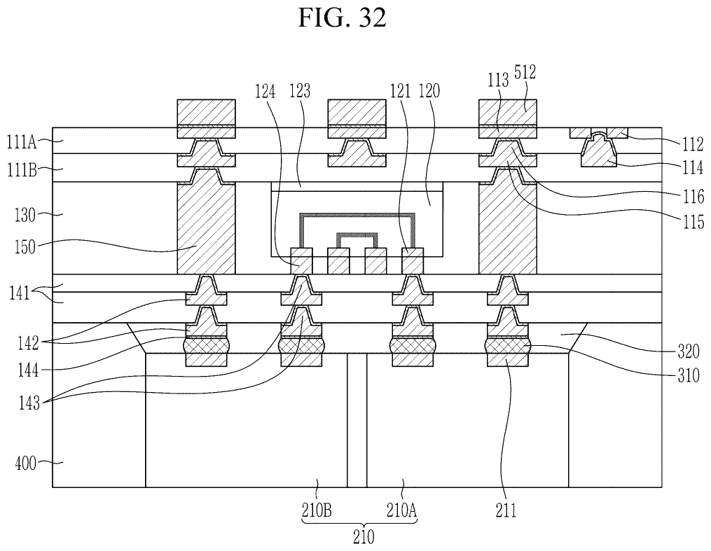

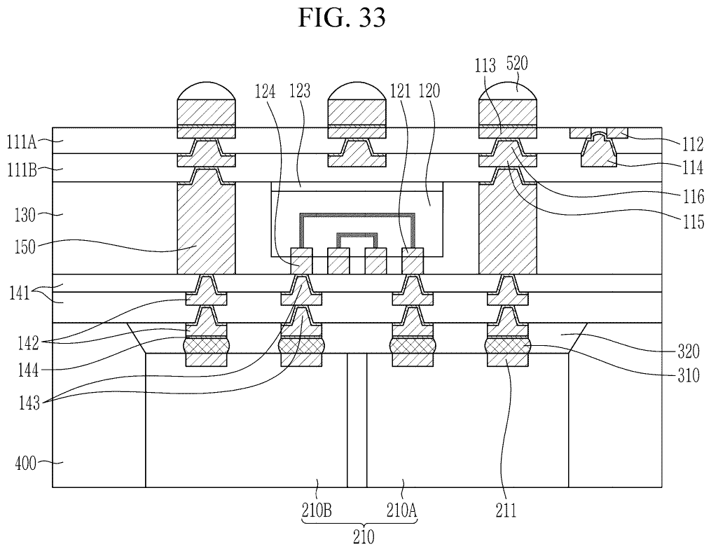

FIG. 11 to FIG. 33 show a process for manufacturing a semiconductor package according to one or more embodiments.

An upper dotted line box in FIG. 25 represents an enlarged view of a region B of FIG. 24, and a lower dotted line box represents an upper diagram of the upper dotted line box.

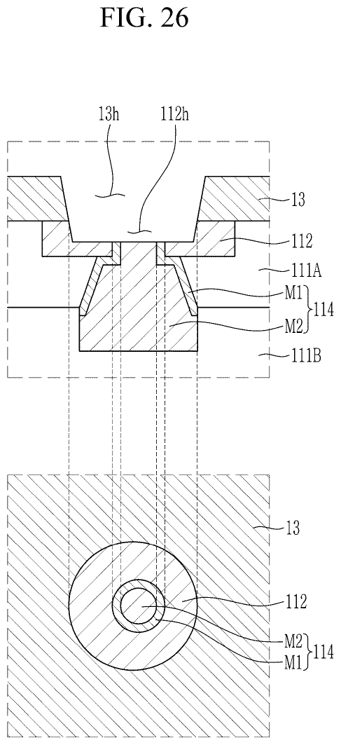

An upper dotted line box in FIG. 26 represents a variation of a region B of FIG. 24, and a lower dotted line box represents an upper diagram of the upper dotted line box.

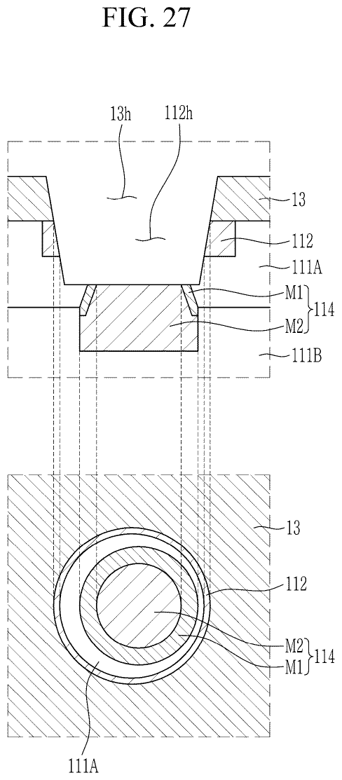

An upper dotted line box in FIG. 27 represents another variation of a region B of FIG. 24, and a lower dotted line box represents an upper diagram of the upper dotted line box.

The first insulation layer 111A is shown to be transparent in FIG. 25 to FIG. 27.

A method for manufacturing a semiconductor package may include manufacturing a substrate 100, arranging a semiconductor chip 210 on the substrate 100, and forming bump structures 500 on an opposite surface to a surface on which the semiconductor chip 210 of the substrate 100 is arranged.

The manufacturing of a substrate 100 may include forming a first aligning pattern 112 with an opening 112h on a conductive foil layer 13, forming an under bump pattern 113 in parallel to the first aligning pattern 112, forming a first insulation layer 111A for covering at least a portion of each of the first aligning pattern 112 and the under bump pattern 113, and forming a second aligning pattern 114 including a first area a1 arranged on the first aligning pattern 112 and embedded in the first insulation layer 111A so that at least a portion thereof may overlap the opening 112h of the first aligning pattern 112.

The process for manufacturing a semiconductor package 1 may include, prior to forming the bump structures 500, exposing the first aligning pattern 112 performing an align key function by removing at least a portion of the conductive foil layer 13. According to one or more embodiments, when a penetration defect is generated to the first aligning pattern 112 in the process for exposing the first aligning pattern 112, the position of the under bump patterns 113 may be recognized through the second aligning pattern 114 and the formation positions of the bump structures 500 may be set.

A method for manufacturing a semiconductor package 1 according to one or more embodiments will now be described in detail.

Referring to FIG. 11, a carrier structure 10 with a surface on which the conductive foil layer 13 is arranged is provided.

The carrier structure 10 may include an insulation substrate 11 and a metal thin film 12 arranged on at least one surface of the insulation substrate 11, and for example, the metal thin film 12 may be a copper clad laminate (CCL).

The conductive foil layer 13 may have an appropriate thickness in the vertical direction to control warpage in the process for manufacturing a semiconductor package. The thickness of the conductive foil layer 13 may be greater than the thickness of the metal thin film 12 in the vertical direction. For example, the thickness of the conductive foil layer 13 may be 3 μm to 5 μm. Further, to be described, the conductive foil layer 13 may be processed in a thin film form, and may function as a seed layer when manufacturing the conductive pillar 510.

A material of the conductive foil layer 13 may use a conductive material, and for example, it may use metal such as copper (Cu), aluminum (Al), gold (Au), platinum (Pt), silver (Ag), tin (Sn), chromium (Cr), palladium (Pd), or titanium (Ti), or two or more alloys thereof.

A release layer may be disposed between the metal thin film 12 and the conductive foil layer 13.

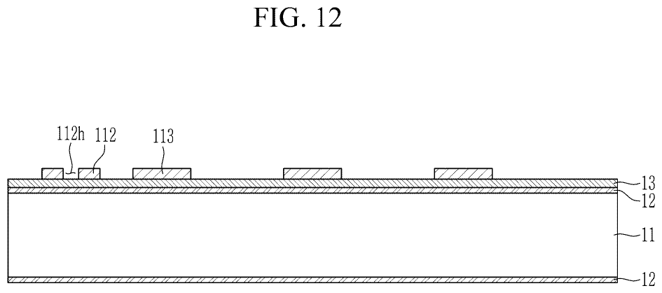

Referring to FIG. 12, a first aligning pattern 112 with an opening 112h and under bump patterns 113 are formed on the conductive foil layer 13. The first aligning pattern 112 and the under bump patterns 113 may be formed by the same process, for example, the plating process, and they may include the same material/may have the same thickness in the vertical direction.

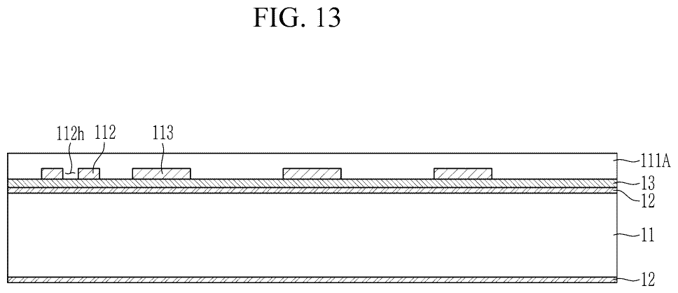

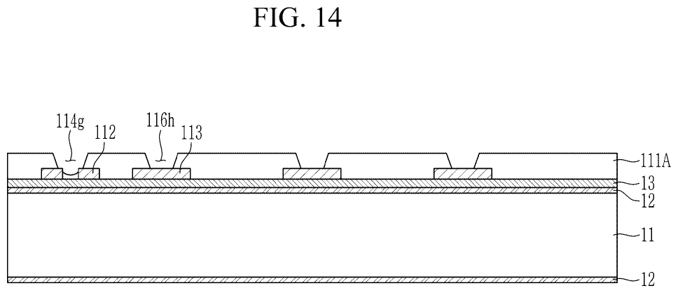

Referring to FIG. 13 and FIG. 14, a first insulation layer 111A may be provided on the first aligning pattern 112 and the under bump patterns 113 may be formed, and a pattern groove 114g and a via hole 116h may be formed on the first insulation layer 111A. The pattern groove 114g and the via hole 116h may be formed by exposing and developing the first insulation layer 111A. When processing the first insulation layer 111A for forming the pattern groove 114g, the first aligning pattern 112 may not be processed and may be exposed through the first insulation layer 111A.

The pattern groove 114g and the via hole 116h may be formed together. When considering a processing time of the first insulation layer 111A applied at the time of forming the via hole 116h, a portion of the first insulation layer 111A in the thickness direction (vertical direction) may be processed, and the first insulation layer 111A may be arranged on the bottom of the pattern groove 114g.

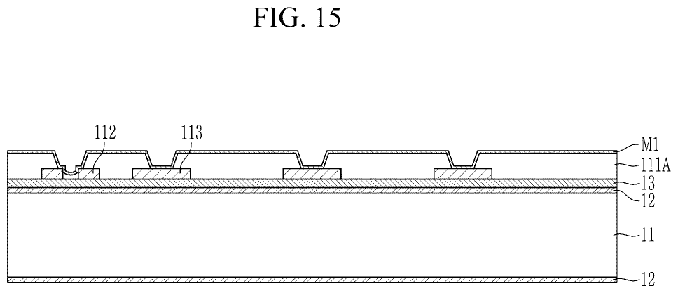

Referring to FIG. 15 to FIG. 17, a second aligning pattern 114, a wire pattern 115, and a via 116 are formed. The second aligning pattern 114, the wire pattern 115, and the via 116 may be formed by forming a thin film portion M1 along a surface of the first insulation layer 111A, a surface of the first aligning pattern 112 exposed through the pattern groove 114g, and a surface of the under bump pattern 113 exposed through the via hole 116h by a deposition process, forming a filling portion M2 in a region that corresponds to a region in which the second aligning pattern 114, the wire pattern 115, and the via 116 of the thin film portion M1 are formed, and removing a region in which the filling portion M2 of the thin film portion M1 is not formed.

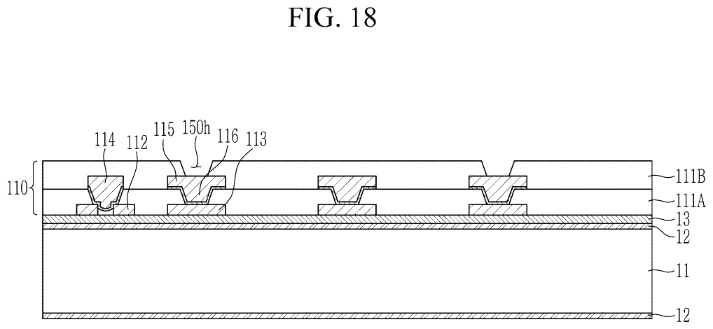

Referring to FIG. 18, a second insulation layer 111B is formed to form a first redistribution structure 110. A hole 150h for forming the conductive post 150 may be formed on the second insulation layer 111B of the first redistribution structure 110.

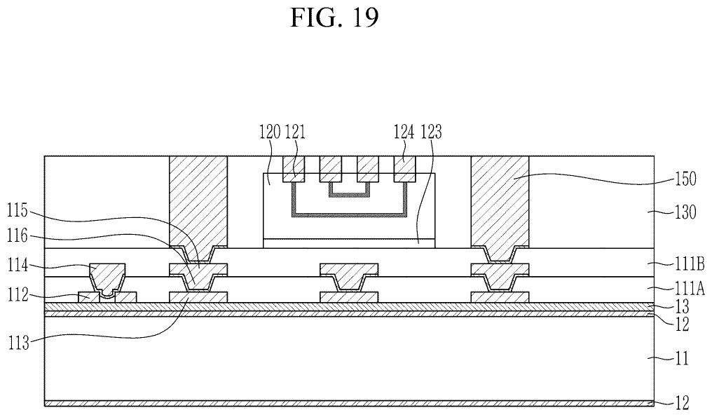

Referring to FIG. 19, a bridge chip 120 is arranged in the first redistribution structure 110, a conductive post 150 and a conductive pillar 124 are formed, and the bridge chip 120, the conductive post 150, and the conductive pillar 124 are encapsulated with the first encapsulant 130. The conductive post 150 and the conductive pillar 124 may be exposed through an upper surface of the first encapsulant 130, and the first encapsulant 130 may be ground to additionally remove a portion of the first encapsulant 130 in the thickness direction (vertical direction).

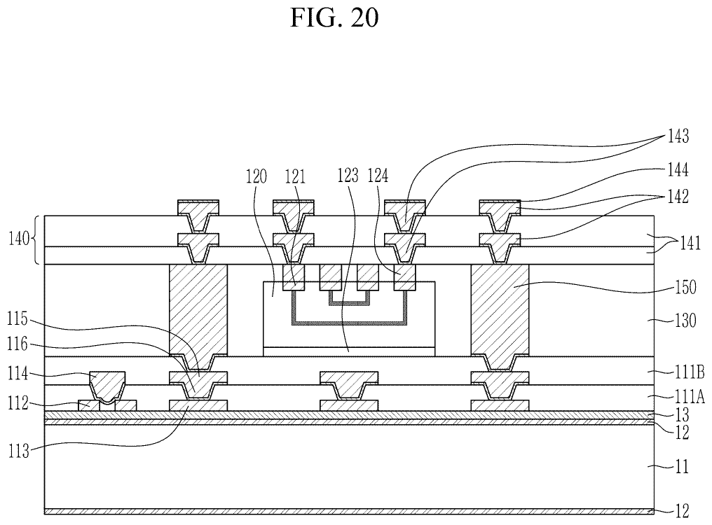

Referring to FIG. 20, a second redistribution structure 140 electrically connected to the conductive pillar 124 and the conductive post 150 is formed on the first encapsulant 130. The second redistribution structure 140 may be formed by sequentially repeatedly forming the insulation layer 141, the via 143, and the wire patterns 142.

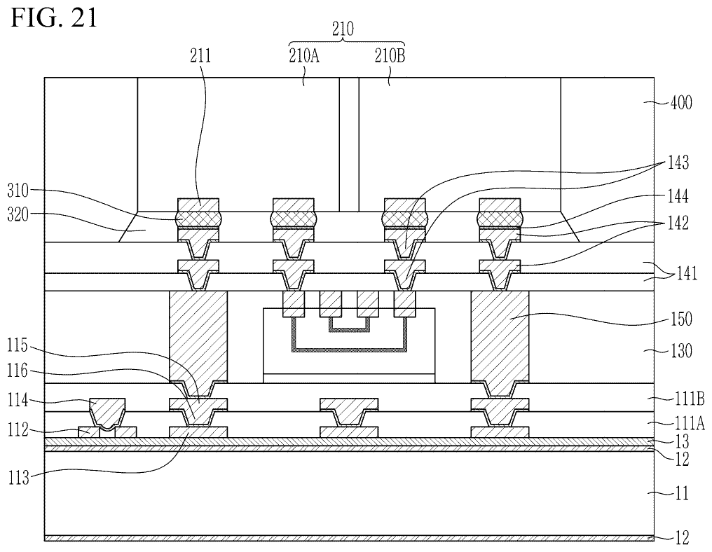

Referring to FIG. 21, semiconductor chips 210 are arranged on the second redistribution structure 140, and are encapsulated with the second encapsulant 400. Upper surfaces of the semiconductor chips 210 may be exposed through an upper surface of the second encapsulant 400, and the second encapsulant 400 may be ground to additionally remove a portion of the second encapsulant 400 in the thickness direction (vertical direction).

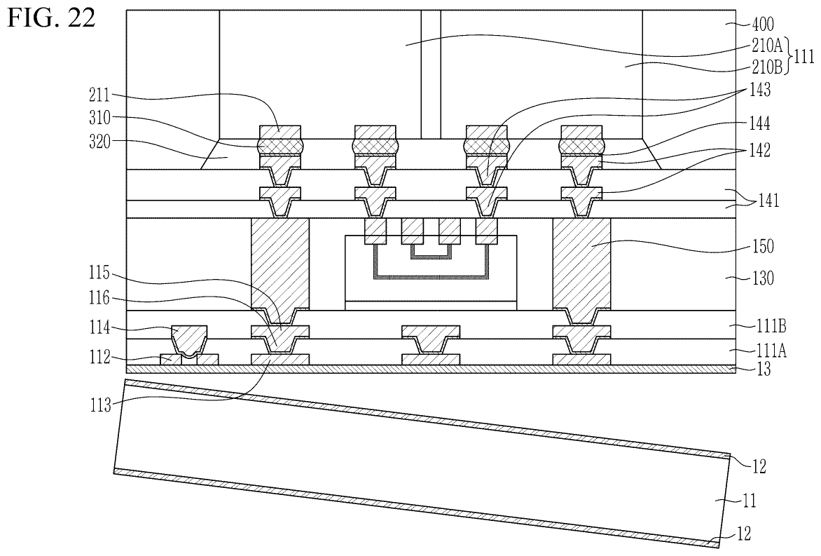

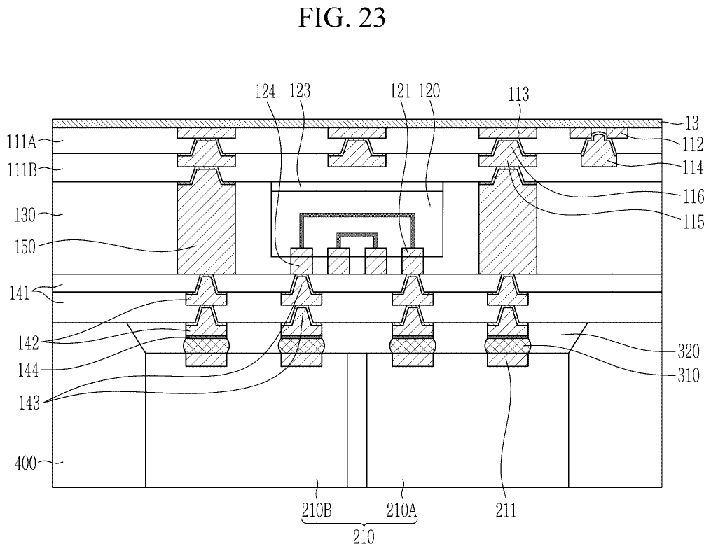

Referring to FIG. 22 and FIG. 23, a carrier structure 10 is removed. The carrier structure 10 may, for example, be removed by separating the conductive foil layer 13 and the metal thin film 12, and the conductive foil layer 13 may be combined to the first redistribution structure 110.

Referring to FIG. 24, the first aligning pattern 112 may be exposed to remove at least a portion of the conductive foil layer 13.

FIG. 25 to FIG. 27 show that a region of the first aligning pattern 112 exposed by processing the conductive foil layer 13 is arbitrarily provided, and the region of the first aligning pattern 112 exposed by processing the conductive foil layer 13 is modifiable depending on implementations.

Referring to FIG. 25, the opening 112h of the first aligning pattern 112 and the region disposed near the opening 112h may be exposed by removing the conductive foil layer 13. In one or more embodiments, when the conductive foil layer 13 is removed, the first aligning pattern 112 may not be processed. The position of the opening 112h of the first aligning pattern 112 may be recognized in a subsequent process by a recognition device such as a mono camera, and the formation position of the bump structure 500 may be set based on the position of the opening 112h. When the second aligning pattern 114 exists, the second aligning pattern 114 includes the material that is different from a material included in the first aligning pattern 112, so they are recognized as different elements, and the position of the opening 112h of the first aligning pattern 112 may be provided.

Referring to FIG. 26, in one or more other, the first aligning pattern 112 may be processed together when the conductive foil layer 13 is removed. The processing depth may be equal to or less than the thickness of the first aligning pattern 112 in the vertical direction, and a portion of the second area a2 of the second aligning pattern 114 may be removed together. For example, the position of the opening 112h of the first aligning pattern 112 may be recognized by a recognition device such as a mono camera, and the formation position of the bump structure 500 may be set based on the position of the opening 112h.

Referring to FIG. 27, in another embodiment, the first aligning pattern 112 may be processed together when the conductive foil layer 13 is removed. When the processing depth is equal to or greater than the thickness of the first aligning pattern 112 in the vertical direction, the entire region disposed near the opening 112h of the first aligning pattern 112 in the thickness direction (vertical direction) may be removed, and the opening 112h may extend to the processing region to thus generate a penetration defect. Performing an align key function based on the first aligning pattern 112 with the extended opening may be difficult. For example, the second aligning pattern 114 may be exposed through the processing region and may be recognized by a recognition device such as a mono camera, and the formation position of the bump structure 500 may be set based on the position of the recognized second aligning pattern 114. According to one or more embodiments, the aligning position may be obtained through the second aligning pattern 114 when the penetration defect is generated.

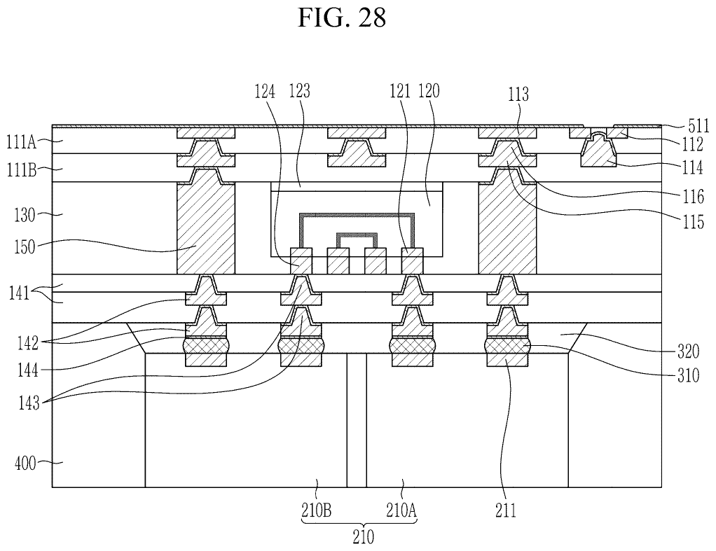

Referring to FIG. 28, a thin film portion 511 is formed by removing a portion of the conductive foil layer 13 in the thickness direction (vertical direction). A portion of the conductive foil layer 13 may, for example, be removed by half etching. According to one or more embodiments, for better understanding and ease of description, different terms and signs are used to the conductive foil layer 13 and the thin film portion 511 formed by processing the conductive foil layer 13.

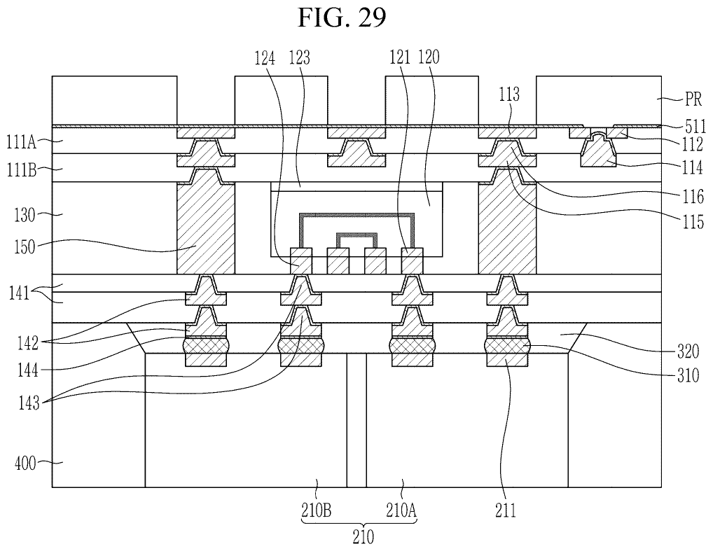

Referring to FIG. 29 to FIG. 33, the semiconductor package 1 according to one or more embodiments may be provided by forming the bump structure 500 including the conductive pillar 510 and the conductive bump 520. A photolithography process may be used in manufacturing the conductive pillar 510. For example, the conductive pillar 510 may be formed by arranging the patterned photoresist layer (PR) on the thin film portion 511, forming the filling portion 512 by using the thin film portion 511 as a seed layer by a plating process, removing the photoresist layer (PR), and removing the thin film portion 511 covered by the photoresist layer (PR). When patterning the photoresist layer (PR), a more accurate exposure position of the photoresist layer (PR) may be set regardless of the penetration defect of the first aligning pattern 112, and the bump structure 500 may be aligned.

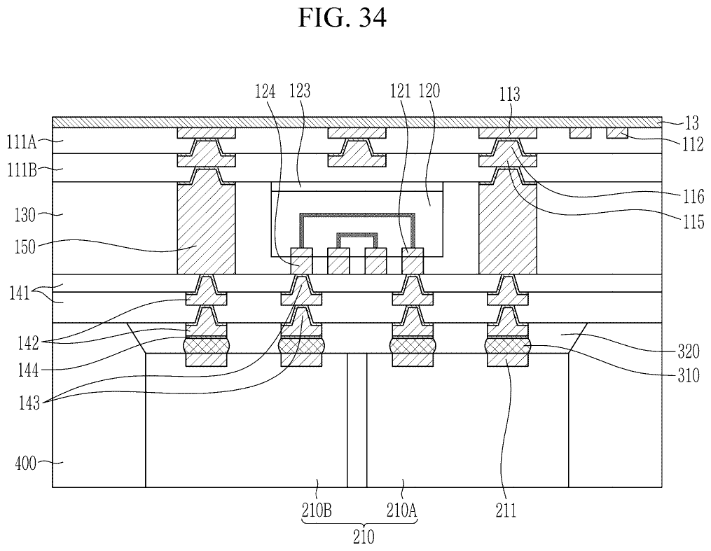

FIG. 34 to FIG. 37 show a partial process for manufacturing a semiconductor package according to a related embodiment.

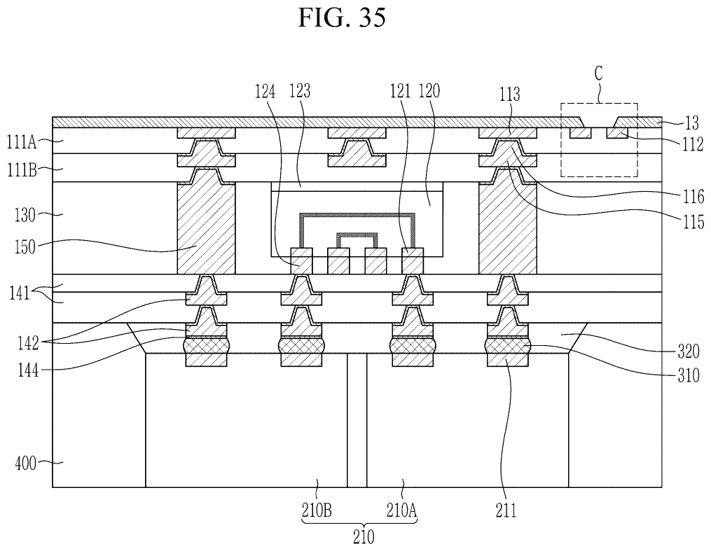

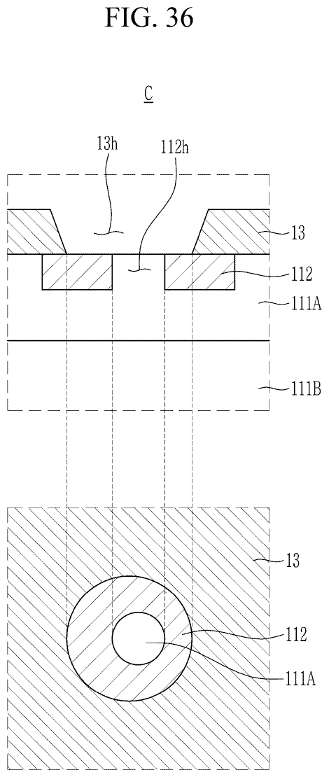

An upper dotted line box in FIG. 36 is an enlarged view of a region C of FIG. 35, and a lower dotted line box is an upper diagram of the upper dotted line box.

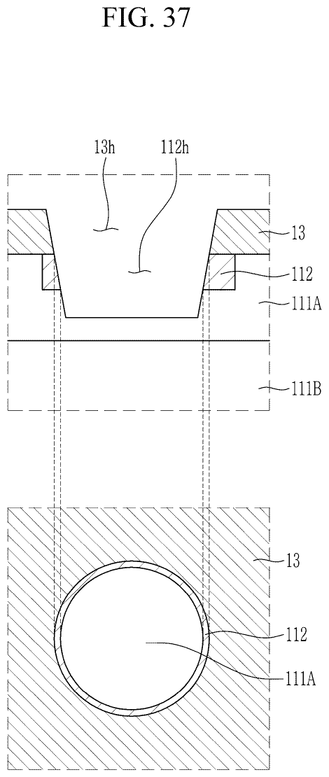

An upper dotted line box in FIG. 37 is a variation of a region C of FIG. 35, and a lower dotted line box is an upper diagram of the upper dotted line box.

A semiconductor package according to a comparative example includes a first aligning pattern 112 and does not include the second aligning pattern 114.

Referring to FIG. 34 and FIG. 35, the first aligning pattern 112 may be exposed by removing at least a portion of the conductive foil layer 13 while manufacturing a semiconductor package according to a related embodiment.

FIG. 34 and FIG. 35 arbitrarily show a region of the first aligning pattern 112 exposed by processing the conductive foil layer 13.

Referring to FIG. 36, the conductive foil layer 13 may be removed from the semiconductor package according to a related embodiment so the opening 112h of the first aligning pattern 112 and the region disposed near the same may be exposed. At the time of removing the conductive foil layer 13, when no penetration defect is generated to the first aligning pattern 112, the position of the opening 112h of the first aligning pattern 112 may be recognized by a recognition device such as a mono camera, and the formation position of the bump structure 500 may be set based on the position of the recognized opening 112h.

Referring to FIG. 37, at the time of removing the conductive foil layer 13, when a penetration defect is generated to the first aligning pattern 112, performing align key function based on the first aligning pattern 112 with the extended opening may be difficult.

On the contrary, according to one or more embodiments, when the penetration defects are generated to the first aligning pattern 112, the formation position of the bump structures 500 may be set by recognizing the position of the under bump patterns 113 through the second aligning pattern 114.

Although embodiments have been described in detail, the scope of the present disclosure is not limited by the embodiments. Various changes and modifications using the basic concept of the present invention defined in the accompanying claims by those skilled in the art shall be construed to belong to the scope of the present disclosure.

The embodiments of the present disclosure are not independent of each other and may be practiced in combination with each other unless specifically contradictory. Therefore, the embodiments that combine embodiments of the present disclosure should also be considered included in the present disclosure.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a substrate comprising:
a first aligning pattern that comprises an opening;
an under bump pattern parallel to the first aligning pattern;
an insulation layer on at least a portion of each of the first aligning pattern and the under bump pattern; and
a second aligning pattern comprising a first area on the first aligning pattern, at least a portion of the first area of the second aligning pattern overlapping the opening of the first aligning pattern and being embedded in the insulation layer;
a bump structure on the under bump pattern; and
at least one semiconductor chip on the substrate opposite to the bump structure,
wherein the second aligning pattern comprises a material that is different from a material included in the first aligning pattern.

2. The semiconductor package of claim 1, wherein the second aligning pattern further comprises a second area extending from the first area and filling at least a portion of the opening of the first aligning pattern.

3. The semiconductor package of claim 2, wherein the insulation layer fills another portion of the opening of the first aligning pattern.

4. The semiconductor package of claim 2, wherein the second area of the second aligning pattern is exposed through the insulation layer.

5. The semiconductor package of claim 2, wherein a width of the second area of the second aligning pattern is less than a width of the first area of the second aligning pattern in a horizontal direction.

6. The semiconductor package of claim 2, wherein the second area of the second aligning pattern contacts the first aligning pattern, the second area of the second aligning pattern comprising a filling portion and a thin film portion between the filling portion and the first aligning pattern, and
wherein the thin film portion comprises a material that is different from the material included in the first aligning pattern.

7. The semiconductor package of claim 2, wherein the opening of the first aligning pattern comprising a first opening region having a first width and a second opening region extending from the first opening region and having a second width that is greater than the first width in a horizontal direction, and
wherein the second area of the second aligning pattern fills at least a portion of the first opening region and is exposed through the second opening region.

8. The semiconductor package of claim 1, wherein the insulation layer comprises a groove portion extending from the opening of the first aligning pattern, and
wherein the first area of the second aligning pattern is exposed through the groove portion of the insulation layer.

9. The semiconductor package of claim 1, wherein a width of the first area of the second aligning pattern in a horizontal direction decreases in a vertical direction from the second aligning pattern to the first aligning pattern.

10. The semiconductor package of claim 1, wherein the insulation layer is transparent or translucent.

11. The semiconductor package of claim 1, wherein the second aligning pattern further comprises a third area on the first area and protruding from the insulation layer.

12. The semiconductor package of claim 11, wherein a width of the third area of the second aligning pattern is equal to or less than a width of the first area of the second aligning pattern in a horizontal direction at an interface of the first area of the second aligning pattern and the third area of the second aligning pattern.

13. The semiconductor package of claim 1, wherein the bump structure comprises a conductive pillar and a conductive bump on the conductive pillar.

14. The semiconductor package of claim 1, wherein the second aligning pattern is on a first surface of the first aligning pattern, and
wherein a second surface of the first aligning pattern, a second surface of the under bump pattern, and a second surface of the insulation layer are coplanar.

15. The semiconductor package of claim 1, wherein the first aligning pattern includes copper, and
wherein the second aligning pattern includes titanium.

16. A semiconductor package comprising:
a substrate comprising:
a first redistribution structure;
a bridge chip on a first surface of the first redistribution structure;
a first encapsulant on at least a portion of the bridge chip;
a second redistribution structure on the first encapsulant and electrically connected to the bridge chip; and
a conductive post embedded in the first encapsulant and electrically connecting the first redistribution structure and the second redistribution structure;
a bump structure on a second surface of the first redistribution structure;
a first semiconductor chip on the second redistribution structure and electrically connected to the second redistribution structure;
a second semiconductor chip on the second redistribution structure and electrically connected to the second redistribution structure, the second semiconductor chip being parallel to the first semiconductor chip; and
a second encapsulant on at least a portion of each of the first semiconductor chip and the second semiconductor chip,
wherein the first redistribution structure comprises:
a first aligning pattern comprising an opening;
an under bump pattern which parallel to the first aligning pattern, the bump structure being on the under bump pattern;
an insulation layer on at least a portion of each of the first aligning pattern and the under bump pattern; and
a second aligning pattern comprising a first area on the first aligning pattern, at least a portion of the first area of the second aligning pattern overlapping the opening of the first aligning pattern and being embedded in the insulation layer and a second area in the opening of the first aligning pattern,
wherein the bridge chip electrically connects the first semiconductor chip and the second semiconductor chip, and
wherein the second aligning pattern comprises a material that is different from a material included in the first aligning pattern.

17. The semiconductor package of claim 16, wherein the first redistribution structure further comprises a wire pattern on the insulation layer and a via embedded in the insulation layer and connecting the under bump pattern and the wire pattern, and
wherein a width of the via in a horizontal direction decreases in a vertical direction from the wire pattern to the under bump pattern.

18. The semiconductor package of claim 17, wherein the first area of the second aligning pattern is parallel to the via.

19. A semiconductor package comprising:
a substrate comprising:
a first aligning pattern comprising an opening;
an under bump pattern parallel to the first aligning pattern;
a first insulation layer on at least a portion of each of the first aligning pattern and the under bump pattern;
a second aligning pattern comprising a first area on the first aligning pattern, at least a portion of the first area of the second aligning pattern overlapping the opening of the first aligning pattern and being embedded in the first insulation layer, and a second area in the opening of the first aligning pattern;
a first wire pattern on the first insulation layer;
a second insulation layer on at least a portion of each of the second aligning pattern and the first wire pattern; and
a second wire pattern on the second insulation layer;
a bump structure on the under bump pattern;
a first semiconductor chip on the substrate opposite to the bump structure, and electrically connected to the substrate;
a second semiconductor chip on the substrate and electrically connected to the substrate, the second semiconductor chip being parallel to the first semiconductor chip; and
an encapsulant on at least a portion of each of the first semiconductor chip and the second semiconductor chip,
wherein the substrate electrically connects the first semiconductor chip and the second semiconductor chip, and
wherein the second aligning pattern comprises a material that is different from a material included in the first aligning pattern.

20. The semiconductor package of claim 19, wherein the substrate further comprises a first via embedded in the first insulation layer and connecting the under bump pattern and the first wire pattern, and a second via embedded in the second insulation layer and connecting the first wire pattern and the second wire pattern, and
wherein a width of the first via and a width of the second via in a horizontal direction decreases in a vertical direction from the second wire pattern to the under bump pattern.
